(19) United States
(12) Patent Application Publication
(10) Pub. No.: US 2025/0157983 A1
(43) Pub. Date: May 15, 2025

(54) SEMICONDUCTOR PACKAGE

(71) Applicant: SAMSUNG ELECTRONICS CO., LTD., SUWON-SI, (KR)

(72) Inventor: HYUNGJUN JEON, Suwon-si (KR)

(21) Appl. No.: 18/753,011

(22) Filed: Jun. 25, 2024

(30) Foreign Application Priority Data
Nov. 10, 2023 (KR) 10-2023-0155615

(51) Int. Cl. H01L 25/065; H01L 23/00; H01L 23/48; H01L 23/498; H01L 23/538; H10B 80/00

(52) U.S. Cl. CPC H01L 25/0652; H01L 23/481; H01L 23/5383; H01L 24/05; H01L 24/06; H01L 24/08; H01L 24/80; H01L 23/49816; H01L 24/16; H01L 24/32; H01L 24/73; H01L 2224/05647; H01L 2224/06181; H01L 2224/08146; H01L 2224/16227; H01L 2224/32225; H01L 2224/73204; H01L 2224/80379; H10B 80/00

(57) ABSTRACT

A semiconductor package includes a base chip including a first via and chip stacks on the base chip. The base chip comprises a first protection layer provided in an upper portion, wherein each of the chip stacks includes a second protection layer, a plurality of memory chips on the second protection layer, and a second via, wherein the first protection layer is in contact with the second protection layer in the lowermost chip stacks, wherein the second via penetrates the plurality of memory chips, wherein the first via has a tapered shape where a width of the first via decreases as a distance to the bottom surface of the base chip along the third direction decrease, and wherein the second via has a tapered shape where a width of the second via increases as a distance from the bottom surface of the base chip along the third direction increases.

### CROSS-REFERENCE TO RELATED APPLICATIONS

This U.S. non-provisional patent application claims priority under 35 U.S.C. § 119 to Korean Patent Application No. 10-2023-0155615, filed on Nov. 10, 2023, in the Korean Intellectual Property Office, the disclosure of which is incorporated by reference herein in its entirety.

### BACKGROUND OF THE INVENTION

The present disclosure relates to a stack-type semiconductor package and a method of fabricating the same, in which a plurality of semiconductor chips are stacked on a package substrate.

With the development of the electronic industry, demand for smaller and greater functionality electronic devices is growing. Accordingly, semiconductor devices used in the electronic devices are also expected to have reduced sizes and more functions. Thus, a semiconductor package technology has been proposed in which a plurality of vertically stacked semiconductor chips is connected using through-silicon vias (TSVs).

### SUMMARY

According to an embodiment of the inventive concept, a semiconductor package includes a first via and chip stacks on the base chip. The base chip includes a first protection layer provided in an upper portion, wherein each of the chip stacks comprises a second protection layer, a plurality of memory chips on the second protection layer, and a second via, wherein the first protection layer is in contact with the second protection layer in the lowermost chip stacks, wherein the second via penetrates the plurality of memory chips, wherein the first via has a tapered shape where a width of the first via decreases as a distance to the bottom surface of the base chip along the third direction decrease, and wherein the second via has a tapered shape where a width of the second via increases as a distance from the bottom surface of the base chip along the third direction increases.

According to an embodiment of the inventive concept, a semiconductor package includes a base chip and chip stacks on the base chip. The base chip includes a first semiconductor substrate, wherein each of the chip stacks comprises a plurality of memory chips and a plurality of first vias, wherein each of the memory chips comprises a second semiconductor substrate and an interconnection layer on the second semiconductor substrate, wherein the first semiconductor substrate has a first thickness along a first direction perpendicular to a top surface of the base chip, wherein the second semiconductor substrate has a second thickness along the first direction, wherein the second thickness is smaller than or equal to 10% of the first thickness, and wherein the plurality of the first vias penetrate the plurality of memory chips.

According to an embodiment of the inventive concept, a semiconductor package includes a package substrate, an interposer substrate on the package substrate, a chip structure disposed on the interposer substrate and a logic chip disposed on the interposer substrate and spaced apart from the chip structure along a first direction parallel to a top surface of the package substrate. The chip structure includes a base chip including a first via, chip stacks on the base chip and a dummy plate on the chip stacks. The base chip comprises a first semiconductor substrate and a first protection layer on the first semiconductor substrate, wherein the chip stacks comprise a second protection layer, a plurality of memory chips on the second protection layer, and a second via, wherein the memory chips comprise a second semiconductor substrate and an interconnection layer on the second semiconductor substrate, wherein the interconnection layer of an uppermost memory chips in each of the chip stacks comprises a landing pad, wherein the second protection layer comprises a connection pad, wherein the dummy plate comprises a third semiconductor substrate, wherein the first semiconductor substrate has a first thickness along a second direction perpendicular to the top surface of the package substrate, wherein the second semiconductor substrate has a second thickness along the second direction. The first thickness is larger than or equal to about 100 μm, wherein the second thickness ranges from 0 μm to about 10 μm, wherein the first protection layer is in contact with the second protection layer, which is included in an lowermost chip stacks, and wherein a width of the second via along the first direction is larger than a width of the first via along the first direction.

### BRIEF DESCRIPTION OF THE DRAWINGS

FIG. 1 is a plan view illustrating a semiconductor package according to an embodiment of the inventive concept.

FIG. 2 is a cross-sectional view taken along a line A-A′ of FIG. 1.

FIG. 3 is an enlarged cross-sectional view illustrating a chip structure and a first mold layer of FIG. 2.

FIG. 4 is an enlarged cross-sectional view illustrating a portion ‘CU’ of FIG. 3.

FIGS. 5A, 5B, 5C, 5D, 5E, 5F and 5G are diagrams illustrating a method of fabricating a semiconductor package, according to an embodiment of the inventive concept.

### DETAILED DESCRIPTION

Example embodiments of the inventive concepts will now be described more fully with reference to the accompanying drawings, in which example embodiments are shown.

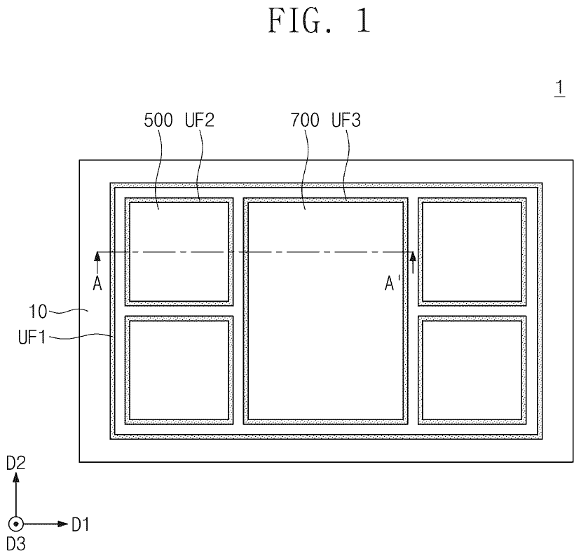

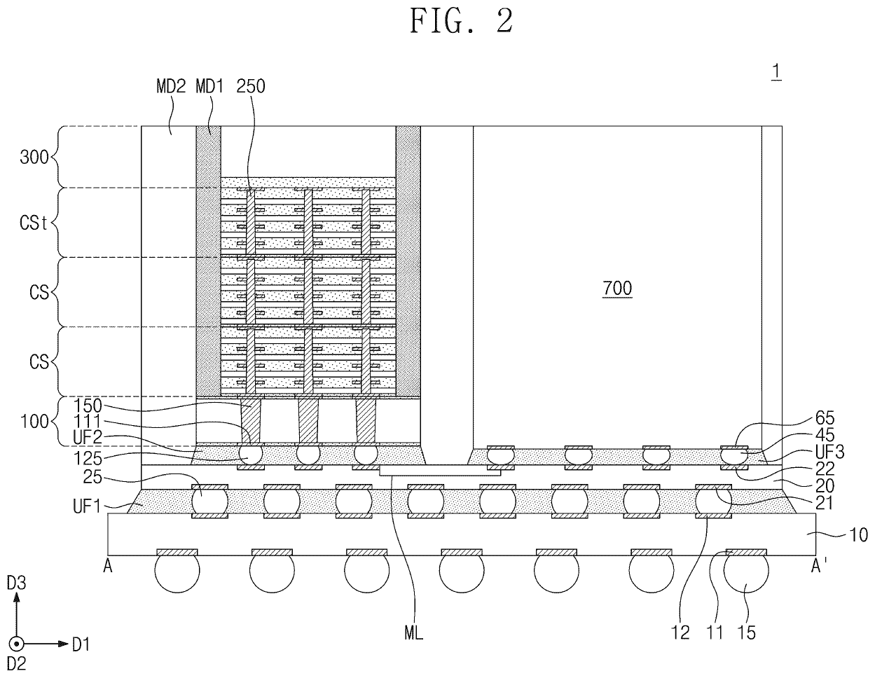

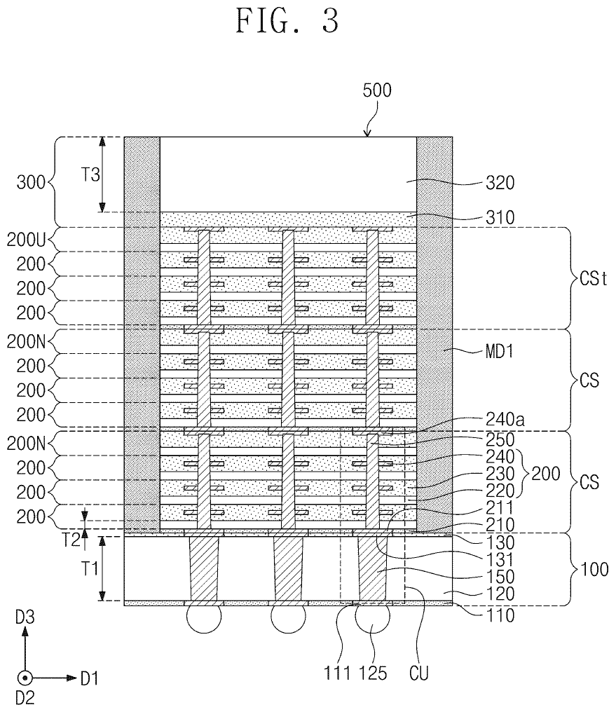

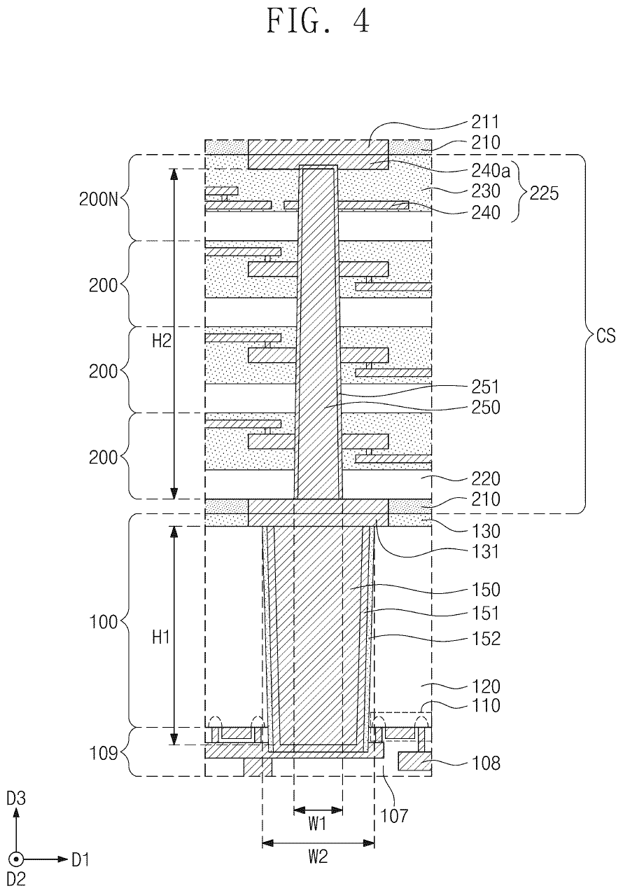

FIG. 1 is a plan view illustrating a semiconductor package according to an embodiment of the inventive concept. FIG. 2 is a cross-sectional view taken along a line A-A′ of FIG. 1. FIG. 3 is an enlarged cross-sectional view illustrating a chip structure and a first mold layer of FIG. 2. FIG. 4 is an enlarged cross-sectional view illustrating a portion ‘CU’ of FIG. 3.

Referring to FIGS. 1 to 4, a semiconductor package 1 may include a package substrate 10, an interposer substrate 20, a chip structure 500, and a logic chip 700.

In the present specification, a first direction D1 may be defined as a direction that is parallel to a top surface of the package substrate 10. A second direction D2 may be defined as a direction that is parallel to the top surface of the package substrate 10 and is perpendicular to the first direction D1. A third direction D3 may be defined as a direction that is perpendicular to the top surface of the package substrate 10.

In an embodiment, the package substrate 10 may be a printed circuit board (PCB). In some embodiments, the package substrate 10 may have a structure, in which insulating layers and interconnection layers are alternately stacked. The package substrate 10 may include a plurality of lower substrate pads 11, which is placed on a bottom surface of the package substrate 10, and a plurality of upper substrate pads 12, which is placed on a top surface of the package substrate 10.

Outer connection terminals 15 may be disposed on the lower substrate pads 11, respectively. The outer connection terminals 15 may include solder balls or solder bumps. Depending on the kind or arrangement of the outer connection terminals 15, the semiconductor package may have a ball grid array (BGA) structure, a fine ball-grid array (FBGA) structure, or a land grid array (LGA) structure. The outer connection terminal 15 may be formed of or include at least one of tin (Sn), silver (Ag), copper (Cu), nickel (Ni), bismuth (Bi), indium (In), antimony (Sb), cerium (Ce), or alloys thereof.

The interposer substrate 20 may be provided on the package substrate 10. In an embodiment, the interposer substrate 20 may be a silicon interposer substrate. The interposer substrate 20 may include a lower interposer pad 21, which is provided on a bottom surface thereof, and an upper interposer pad 22, a metal line, and a penetration electrode, which are provided on a top surface thereof. The chip structure 500 and the logic chip 700 may be electrically connected to the package substrate 10 through the interposer substrate 20.

First connection terminals 25 may be disposed between the package substrate 10 and the interposer substrate 20. For example, each of the first connection terminals 25 may be interposed between the upper substrate pad 12 and the lower interposer pad 21 and may be in contact with the upper substrate pad 12 and the lower interposer pad 21. For example, the first connection terminals 25 may be in direct contact with the upper substrate pad 12 and the lower interposer pad 21. The interposer substrate 20 may be electrically connected to the package substrate 10 through the first connection terminals 25. The first connection terminals 25 may include a metallic material that is substantially the same as or similar to that of the outer connection terminal 15.

A first under-fill layer UF1 may be disposed between the package substrate 10 and the interposer substrate 20. For example, the first under-fill layer UF1 may be disposed adjacent to the first connection terminals 25. The first under-fill layer UF1 may fill a space between the package substrate 10 and the interposer substrate 20 and may at least partially surround side surface of each of the first connection terminals 25. In an embodiment, the first under-fill layer UF1 may be formed of or include an epoxy resin.

The chip structure 500 and the logic chip 700 may be disposed on the interposer substrate 20. In an embodiment, the chip structures 500 may be spaced apart from each other along the first direction D1, with the logic chip 700 interposed therebetween. The chip structures 500 may also be arranged to be spaced apart from each other along the second direction D2. However, the arrangement of the chip structure 500 and the logic chip 700 is not necessarily limited thereto and it may be variously modified depending on the type or design of the semiconductor package.

Referring to FIGS. 3 and 4, the chip structure 500 may include a base chip 100, chip stacks CS, and a dummy plate 300.

The base chip 100 may be called a logic die, a logic chip, a base die, a buffer chip, a buffer die, or a memory controller. The base chip 100 may be used as a logic chip increasing data transmission efficiency and reducing power consumption.

The base chip 100 may include a circuit layer 110, a base interconnection layer 109, a first semiconductor substrate 120, a first via 150, a first protection layer 130, a first upper connection pad 131, and a first lower connection pad 111.

The first semiconductor substrate 120 may be disposed on the circuit layer 110. The first semiconductor substrate 120 may be formed of or include a semiconductor material such as silicon and/or germanium. The first semiconductor substrate 120 may have a first thickness T1 along the third direction D3. The first thickness T1 may be larger than or equal to about 100 μm.

The circuit layer 110 may be disposed below the base chip 100. The circuit layer 110 may include an integrated circuit. For example, the circuit layer 110 may include a memory circuit, a logic circuit, or combinations thereof. In an embodiment, a bottom surface of the base chip 100 may be an active surface. The circuit layer 110 may include an electronic device (e.g., a transistor), an insulating pattern, and an interconnection pattern.

The base interconnection layer 109 may be disposed below the circuit layer 110. The base interconnection layer 109 may include an interconnection insulating layer 107 and an interconnection structure 108 disposed in the interconnection insulating layer 107.

The first protection layer 130 and the first upper connection pad 131 may be disposed on the first semiconductor substrate 120. The first protection layer 130 may be formed of or include at least one of silicon oxide (SiO₂), silicon carbon nitride (SiCN), or silicon oxycarbide (SiCO). The first upper connection pad 131 may be provided in the first protection layer 130, and here, a top surface of the first upper connection pad 131 may be exposed from the first protection layer 130. The first upper connection pad 131 may be formed of or include copper (Cu).

The first lower connection pad 111 may be disposed on the bottom surface of the base chip 100. The first lower connection pad 111 may be electrically connected to the circuit layer 110. In an embodiment, a plurality of first lower connection pads 111 may be provided. The first lower connection pad 111 may be formed of or include copper (Cu).

The first via 150 may be provided and penetrate the base chip 100. For example, the first via 150 may be a protruding pattern that extends from the first upper connection pad 131 and penetrates the first semiconductor substrate 120 and a portion of the base interconnection layer 109. In an embodiment, a plurality of first vias 150 may be arranged along the first direction D1. An end portion of the first via 150 may be connected to the first upper connection pad 131, and an opposite end portion of the first via 150 may be connected to the interconnection structure 108. The first via 150 and the circuit layer 110 may be electrically connected to each other.

The first via 150 may have a second width W2 or a second diameter W2 along the first direction D1. The first via 150 may have a first height H1 along the third direction D3. The second width W2 may be smaller than or equal to about 60 μm. A first aspect ratio, which is a value obtained by dividing the first height H1 by the second width W2, may be less than or equal to 17.

The first via 150 may have a tapered shape. The tapered shape may refer to a form that gradually narrows or widens from one end to another, resembling a cone or a wedge. For example, a width of the first via 150 along the first direction D1 may decrease, as a distance to the bottom surface of the base chip 100 along the third direction D3 decreases.

A first barrier metal 151 may be disposed on side and top surfaces of the first via 150. A liner 152 may be disposed on a side surface of the first barrier metal 151. The liner 152 may be interposed between the first barrier metal 151 and the first semiconductor substrate 120. The first barrier metal 151 may be formed of or include at least one of titanium (Ti), titanium nitride (TiN), or tungsten (W). The liner 152 may be formed of or include at least one of silicon oxide (SiO₂) silicon nitride (SiN), silicon carbon nitride (SiCN), or silicon oxycarbide (SiCO). The first barrier metal 151 and the liner 152 may prevent a metallic material in the first via 150 from diffusing into the first semiconductor substrate 120.

A plurality of second connection terminals 125 may be provided on the bottom surface of the base chip 100. The second connection terminals 125 may be disposed on the first lower connection pads 111, respectively. The second connection terminals 125 may be electrically connected to the circuit layer 110 and the first via 150. The second connection terminals 125 may include a metallic material that is substantially the same as or similar to that of the outer connection terminal 15.

The chip stacks CS may be disposed on the base chip 100. Each of the chip stacks CS may include a second protection layer 210, a plurality of memory chips 200, and a second via 250.

A second protection layer 210 and a second lower connection pad 211 may be disposed in a lower portion of the chip stack CS. The second protection layer 210 may be formed of or include at least one of silicon oxide (SiO₂), silicon carbon nitride (SiCN), or silicon oxycarbide (SiCO). The second lower connection pad 211 may be provided in the second protection layer 210, and here, a top surface of the second lower connection pad 211 may be exposed from the second protection layer 210. The second lower connection pad 211 may include copper (Cu).

Here, the second protection layer 210 and the second lower connection pad 211, which are included in one of the lowermost chip stacks CS on the base chip 100, may be in contact with the first protection layer 130 and the first upper connection pad 131, respectively, which are included in the base chip 100. The first and second protection layers 130 and 210 may be bonded to each other in an oxide-to-oxide bonding manner. As an example, each of the first and second protection layers 130 and 210 may include an oxide material (e.g., silicon oxide (SiO₂)) forming an oxide-to-oxide bonding structure. The first upper connection pad 131 and the second lower connection pad 211 may be bonded to each other in a hybrid bonding manner. In the present specification, the hybrid bonding structure may mean a bonding structure that is formed by two materials, which are of the same kind and are fused at an interface therebetween.

The memory chips 200 may be provided on the second protection layer 210. FIGS. 2 to 4 illustrate an example, in which four memory chips 200 are provided in each chip stack CS, but the inventive concept is not necessarily limited to this example. The number of the memory chips 200, which are included in each chip stack CS, may be 2N, where N is an integer.

Each of the memory chips 200 may include a second semiconductor substrate 220, a circuit layer, and an interconnection layer 225 disposed on the second semiconductor substrate 220.

The second semiconductor substrate 220 may be disposed in a lower portion of each of the memory chips 200. The second semiconductor substrate 220 may include a semiconductor material (e.g., silicon and germanium). In some embodiments, the second semiconductor substrate 220 may not be included in the memory chip 200. The second semiconductor substrate 220 may have a second thickness T2 along the third direction D3. The second thickness T2 of the second semiconductor substrate 220 may be equal to or smaller than 10% of the first thickness T1 of the first semiconductor substrate 120. For example, the second thickness T2 may range from 0 μm to about 10 μm.

The interconnection layer 225 may be disposed on the second semiconductor substrate 220. In an embodiment, the second semiconductor substrate 220 and the interconnection layer 225 may be bonded to each other in an oxide-to-oxide bonding manner, and here, a native silicon oxide layer, which is naturally formed on the second semiconductor substrate 220, may participate in such a bonding process (i.e., the oxide-to-oxide bonding process). That is, the memory chips 200 in the chip stacks CS may be bonded to each other through an oxide-to-oxide bonding structure, not through a pad bonding structure. A circuit layer may be disposed between the second semiconductor substrate 220 and the interconnection layer 225.

The interconnection layer 225 may include a first insulating layer 230 and an interconnection pattern 240. The first insulating layer 230 may include at least one of, for example, silicon oxide (SiO₂), silicon nitride (Si₃N₄), or silicon oxynitride (SiOₓN_{y}). In some embodiments, the first insulating layer 230 may include a plurality of insulating layers. The interconnection pattern 240 may also include a plurality of interconnection lines.

Here, the interconnection pattern 240 in the uppermost memory chip 200N in the chip stack CS or 200U in an uppermost chip stack CSt may include a landing pad 240a, which is provided in an upper portion of the interconnection layer 225.

The landing pad 240a in each chip stack CS may be in contact with the second lower connection pad 211, which is included in another chip stack CS. Here, the landing pad 240a and the second lower connection pad 211 may be bonded to each other in a hybrid bonding manner. For example, the chip stacks CS may be connected to each other through a bonding structure between the landing pad 240a included in one chip stack CS and the second lower connection pad 211 included in another chip stack CS that is disposed on the one chip stack CS.

The first insulating layer 230 of the uppermost memory chip 200N, which is included in each chip stack CS, may be bonded to the second protection layer 210, which is included in another one of the chip stacks CS in an oxide-to-oxide bonding manner. However, the first insulating layer 230 in the uppermost memory chip 200U, which is included in the uppermost chip stack CSt, may be bonded to a second insulating layer 310, which is included in the dummy plate 300, in an oxide-to-oxide bonding manner, and a top surface of the landing pad 240a, which is included in the uppermost memory chip 200U of the uppermost chip stack CSt, may be in contact with a bottom surface of the second insulating layer 310.

The second via 250 may penetrate the memory chips 200, which are included in the chip stack CS. The second via 250 may extend from the second lower connection pad 211, which is included in each chip stack CS, and penetrate the second semiconductor substrate 220 of each memory chip 200 and the interconnection patterns 240 of the interconnection layer 225. For example, the second via 250 may penetrate the interconnection layers 225 of the memory chips 200 in each chip stack CS, but for the uppermost memory chip 200N or 200U, the second via 250 may penetrate a portion of the interconnection layer 225. In an embodiment, a plurality of second vias 250 may be arranged along the first direction D1. An end portion of the second via 250 may be connected to the second lower connection pad 211, and an opposite end portion of the second via 250 may be provided to penetrate a portion of the landing pad 240a in the uppermost memory chip 200N or 200U, which is included the chip stack CS and the uppermost chip stack CSt. The second via 250 may be electrically connected to the first via 150.

The second via 250 may have a first width W1 or a first diameter W1 along the first direction D1. The second via 250 may have a second height H2 along the third direction D3. The second width W2 of the first via 150 may be larger than the first width W1 of the second via 250. The first width W1 may be smaller than or equal to about 10 μm. A second aspect ratio, which is a value obtained by dividing the second height H2 by the first width W2, may be less than or equal to 15.

The second via 250 may have a shape that is tapered in an opposite manner to the first via 150. For example, a width of the second via 250 along the first direction D1 may increase as a distance from the bottom surface of the base chip 100 along the third direction D3 increases.

A second barrier metal 251 may be disposed on side and top surfaces of the second via 250. Here, a liner may not be formed on the second via 250, unlike the first via 150, and due to the absence of the liner, the memory chips 200, which are included in each chip stack CS, may be electrically connected to each other. The second barrier metal 251 may be formed of or include at least one of titanium (Ti), titanium nitride (TiN), or tungsten (W). The second barrier metal 251 may prevent a metallic element, which is included in the second via 250, from diffusing to the second semiconductor substrate 220.

The dummy plate 300 may be disposed on the uppermost chip stack CSt. The dummy plate 300 may include the second insulating layer 310 and a third semiconductor substrate 320 disposed on the second insulating layer 310. The second insulating layer 310 may be formed of or include at least one of silicon oxide (SiO₂), silicon carbon nitride (SiCN), or silicon oxycarbide (SiCO).

The second insulating layer 310 may be in contact with a top surface of the uppermost memory chip 200U, which is included in the uppermost chip stack CSt. The second insulating layer 310 may be in contact with the first insulating layer 230, which is included in the uppermost memory chip 200U of the uppermost chip stack CSt. The first insulating layer 230 and the second insulating layer 310 may be bonded to each other in a hybrid bonding manner.

The third semiconductor substrate 320 may include a semiconductor material (e.g., silicon and germanium). The third semiconductor substrate 320 may not include electronic devices (e.g., an integrated circuit), interconnection patterns, and penetration electrodes. The third semiconductor substrate 320 may have a third thickness T3 along the third direction D3. In an embodiment, the third thickness T3 may range from about 700 μm to about 775 μm.

Referring back to FIG. 3, a first mold layer MD1 may cover a top surface of the base chip 100, side surfaces of the chip stacks CS, and a side surface of the dummy plate 300. The first mold layer MD1 may be formed of or include an insulating material (e.g., an epoxy molding compound (EMC)).

A second under-fill layer UF2 (refer to FIG. 2) may be provided between the chip structure 500 and the interposer substrate 20. The second under-fill layer UF2 may fill a space between the chip structure 500 and the interposer substrate 20 and may at least partially surround a side surface of each of the second connection terminals 125. In an embodiment, the second under-fill layer UF2 may include an epoxy resin.

The logic chip 700 (refer to FIG. 2) may be disposed on the interposer substrate 20. The logic chip 700 may include one of a graphics processing unit (GPU) die, a central processing unit (CPU) die, or a system-on-chip (SoC).

A plurality of chip pads 65 (refer to FIG. 2) may be disposed on a bottom surface of the logic chip 700. Third connection terminals 45 (refer to FIG. 2) may be respectively disposed between the logic chip 700 and the interposer substrate 20. For example, the third connection terminals 45 may be interposed between the chip pad 65 and the upper interposer pad 22 and may be in contact with the chip pad 65 and the upper interposer pad 22. The logic chip 700 may be electrically connected to the package substrate 10 through the third connection terminals 45. The third connection terminals 45 may include a metallic material that is substantially the same as or similar to that of the outer connection terminal 15.

A third under-fill layer UF3 (refer to FIG. 2) may be provided between the logic chip 700 and the interposer substrate 20. The third under-fill layer UF3 may fill a space between the logic chip 700 and the interposer substrate 20 and may enclose a side surface of each of the third connection terminals 45. In an embodiment, the third under-fill layer UF3 may be formed of or include an epoxy resin.

A second mold layer MD2 (refer to FIG. 2) may be disposed on the interposer substrate 20. In detail, the second mold layer MD2 may cover a top surface of the interposer substrate 20. The second mold layer MD2 may enclose the chip structure 500 and the logic chip 700. A top surface of the second mold layer MD2 may be located at substantially the same level as the top surfaces of the chip structure 500 and the logic chip 700. The second mold layer MD2 may include an insulating material (e.g., an epoxy molding compound).

According to an embodiment of the inventive concept, the semiconductor package 1 may include the chip stacks CS including the memory chips 200. Here, a thickness of the second semiconductor substrate 220, which is included in each of the memory chips 200, may range from 0 μm to about 10 μm and may be smaller than or equal to 10% of a thickness of the first semiconductor substrate 120 included in the base chip 100. A height of the chip structure 500 may be reduced, and this may make it possible to reduce a volume of the chip structure 500. Furthermore, by reducing the thickness of the second semiconductor substrate 220 is, it may be possible to increase a thickness of the third semiconductor substrate 320 included in the dummy plate 300, compared to a thickness of a conventional dummy plate 300, and thus improve the heat-dissipation characteristics of the semiconductor package 1.

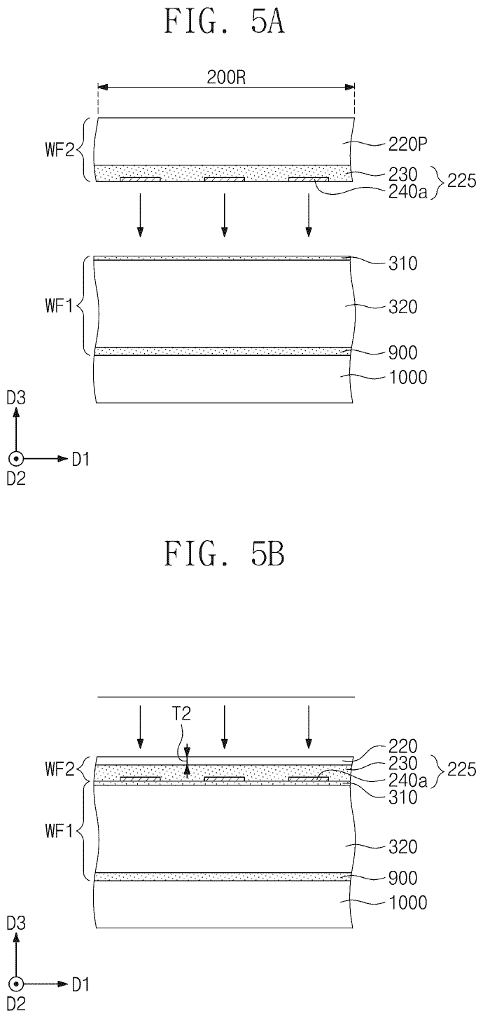

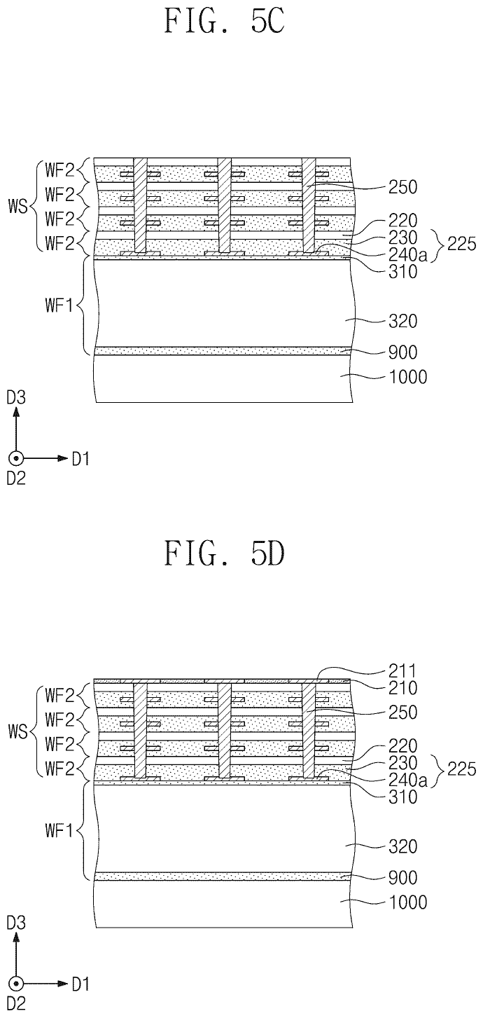

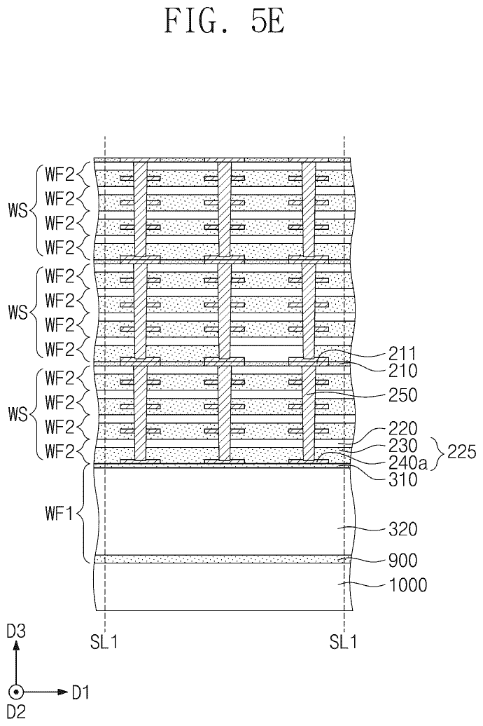

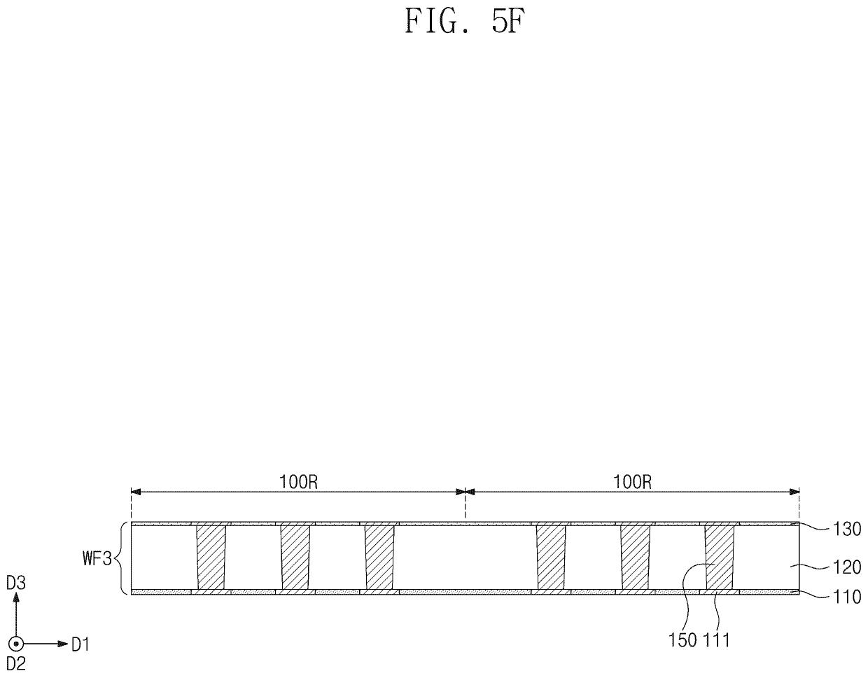

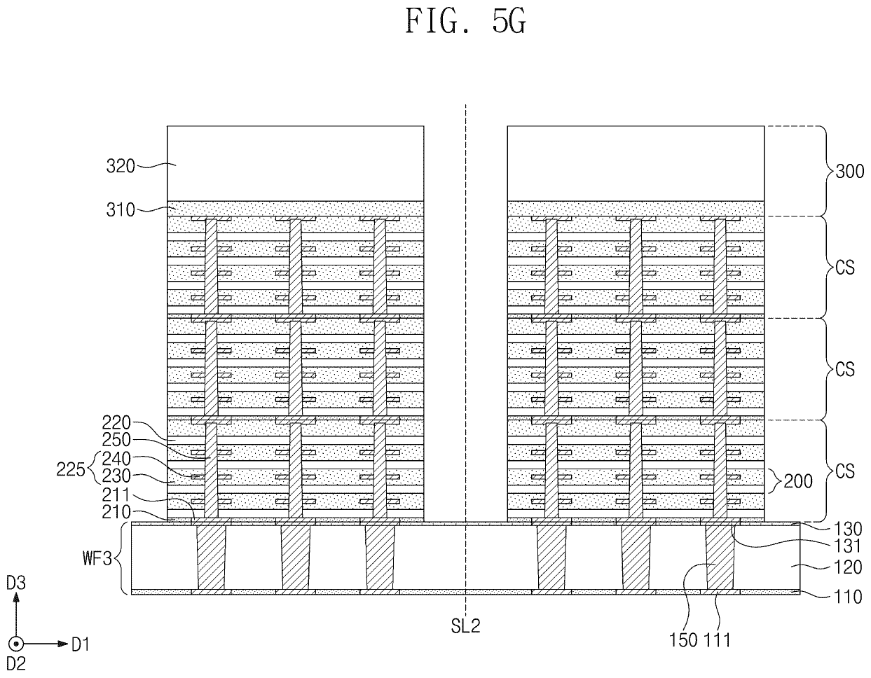

FIGS. 5A to 5G are diagrams illustrating a method of fabricating a semiconductor package, according to an embodiment of the inventive concept.

Referring to FIG. 5A, a carrier substrate 1000 and a release layer 900 disposed on the carrier substrate 1000 may be provided. The carrier substrate 1000 may be an insulating substrate, which is formed of or includes glass or polymer, or a conductive substrate, which is formed of or includes a metallic material. The release layer 900 may include an adhesive tape.

A first wafer WF1 may be provided on the release layer 900. The first wafer WF1 may include a plurality of dummy plate regions. The dummy plate regions may be regions of the first wafer WF1, which are defined when the fabrication process is in a stage before a sawing process, and each of which will be used as the dummy plate 300 after the sawing process. The first wafer WF1 may include the third semiconductor substrate 320 and the second insulating layer 310.

Thereafter, a second wafer WF2 may be bonded to the first wafer WF1. The second wafer WF2 may include a plurality of memory chip regions 200R. The memory chip region 200R may be a region of the second wafer WF2, which is defined when the fabrication process is in a stage before the sawing process, and which will be used as the memory chip 200 after the sawing process. For example, the second wafer WF2 may include a preliminary second semiconductor substrate 220P and the first insulating layer 230, which constitutes the interconnection layer 225. Here, the interconnection layer 225 in the second wafer WF2, which will be bonded to the first wafer WF1, may include the landing pad 240a. The first and second wafers WF1 and WF2 may be bonded to each other through a hybrid bonding structure between the first insulating layer 230 and the second insulating layer 310.

Referring to FIG. 5B, a grinding process may be performed on a top surface of the preliminary second semiconductor substrate 220P and remove a portion of the preliminary second semiconductor substrate 220P. As a result of the grinding process of reducing a thickness of the preliminary second semiconductor substrate 220P along the third direction D3, the second semiconductor substrate 220 may be formed. The second semiconductor substrate 220 may have the second thickness T2. The second thickness T2 may range from 0 μm to about 10 μm.

Referring to FIG. 5C, a wafer stack WS may be formed on the second semiconductor substrate 220 of FIG. 5B. The formation of the wafer stack WS may include repeating a process cycle including steps of bonding the second wafer WF2 and performing the grinding process of FIG. 5B. Here, the second wafers WF2 may be bonded to each other through an oxide-to-oxide bonding structure between the second semiconductor substrate 220 and the first insulating layer 230. Steps of bonding the second wafer WF2 to the second semiconductor substrate 220 and performing the grinding process on the preliminary second semiconductor substrate 220P may be repeated 2N times, where N is a positive integer.

Thereafter, the second vias 250, each of which penetrates a plurality of second wafers WF2, may be formed and arranged in along the first direction D1. Referring back to FIG. 4, the formation of the second via 250 may include forming a via hole through an etching process which exposes an upper portion of the landing pad 240a, forming the second barrier metal 251 on side and bottom surfaces of the via hole, and filling a remaining space of the via hole, in which the second barrier metal 251 is provided, with a metallic material.

Referring to FIG. 5D, the second protection layer 210 may be formed on one of the uppermost second wafers WF2. The second protection layer 210 may include the second lower connection pad 211.

Referring to FIG. 5E, a plurality of wafer stacks WS may be formed on the second protection layer 210 of FIG. 5D. The formation of the wafer stack WS may be substantially the same as described with reference to FIG. 5C. An example, in which the process of FIGS. 5A to 5D is performed three times has been illustrated, but the inventive concept is not necessarily limited to this example. The process of FIGS. 5A to 5D may be performed N times, where N is a positive integer.

Thereafter, the first wafer WF1, the second insulating layer 310, and the second wafers WF2 may be cut along a first sawing line SL1. As a result of this sawing process, the base chip 100 and the chip stacks CS may be formed from the first and second wafers WF1 and WF2, respectively. That is, a plurality of chip structures 500, each of which includes the base chip 100, the second insulating layer 310, and the chip stacks CS, may be formed by the sawing process.

Referring to FIG. 5F, a third wafer WF3 may be provided. The third wafer WF3 may include a plurality of base chip regions 100R. The base chip regions 100R may be regions of the third wafer WF3, which are defined when the fabrication process is in a stage before the sawing process, and each of which will be used as the base chip 100 after the sawing process. The third wafer WF3 may include the circuit layer 110, the first semiconductor substrate 120, the first via 150, and the first protection layer 130. Here, referring back to FIG. 4, the formation of the first via 150 may include forming a via hole through a process of etching an upper portion of the interconnection insulating layer 107, forming the liner 152 on a side surface of the via hole, forming the first barrier metal 151 that covers a bottom surface of the via hole and the liner 152, and filling a remaining space of the via hole, in which the liner 152 and the first barrier metal 151 are formed, with a metallic material.

Referring to FIG. 5G, the chip structures 500, which are prepared by the process of FIG. 5E, may be bonded to the third wafer WF3. The chip structures 500 may be spaced apart from each other along the first direction D1. For example, the first protection layer 130, which is included in one of the lowermost chip stacks CS, may be bonded to the second protection layer 210, which is included in the third wafer WF3, in an oxide-to-oxide bonding manner. The second lower connection pad 211 in the chip structure 500 may be bonded to the first upper connection pad 131 in a hybrid bonding manner.

The third wafer WF3 may be cut along a second sawing line SL2. As a result of this sawing process, the base chip 100 may be formed from the third wafer WF3. In other words, a plurality of chip structures 500, each of which includes the base chip 100 and the chip stacks CS, may be formed by the sawing process.

Referring back to FIG. 2, the semiconductor package 1 may be formed by a chip assembly process of mounting the interposer substrate 20, the logic chip 700, and the chip structure 500 of FIG. 5G on the package substrate 10 and forming the second mold layer MD2.

In a process of fabricating a semiconductor package 1 according to a comparative example, the via 150 may be formed and penetrate each of the memory chips, and then, a thermocompression bonding process may be repeated to bond the memory chips 200 on a wafer WF. In this case, efficiency in the fabricating process may be lowered. Furthermore, the performance of the semiconductor package 1 may be deteriorated due to heat, which is supplied in the thermocompression bonding process.

By contrast, in a process of fabricating a semiconductor package 1 according to an embodiment of the inventive concept, wafers WF including a plurality of memory chips 200 may be stacked and then via patterns may be formed to penetrate them. Thereafter, the memory chips 200 may be bonded to a base chip in an oxide-to-oxide bonding manner and a hybrid bonding manner. In this case, it may be possible to increase a yield in a process of fabricating a semiconductor package 1 and to improve performance and structural stability of the semiconductor package 1.

According to an embodiment of the inventive concept, a semiconductor package 1 may include a base chip 100 and a plurality of chip stacks CS. Here, each of the chip stacks CS may include a plurality of memory chips 200 and a via 150, which is provided to penetrate the memory chips 200. A thickness of a semiconductor substrate 120 included in each of the memory chips 200 may be smaller than or equal to 10% of a thickness of a semiconductor substrate 120 in the base chip. As a result, the volume of the semiconductor package may be reduced.

In addition, the chip stacks CS may be formed through a process of stacking wafers WF, each of which includes a plurality of memory chips 200, and then forming via patterns that penetrates the wafers WF. In this case, it may be possible to improve a yield in a process of fabricating a semiconductor package 1 and performance of the semiconductor package 1.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor package, comprising:
a base chip including a first via; and
chip stacks on the base chip,
wherein the base chip comprises a first protection layer provided in an upper portion,
wherein each of the chip stacks comprises a second protection layer, a plurality of memory chips on the second protection layer, and a second via,
wherein the first protection layer is in contact with the second protection layer in the lowermost chip stacks,
wherein each second via penetrates the plurality of memory chips in each of the chip stacks,
wherein the first via has a shape that tapers with a narrowing width from an end at the base chip to an end away from the base chip and each second via has a shape that tapers with a narrowing width away from the base chip.

2. The semiconductor package of claim 1, wherein the first protection layer and the second protection layer comprise at least one of silicon oxide (SiO₂), silicon carbon nitride (SiCN), or silicon oxycarbide (SiCO).

3. The semiconductor package of claim 1, wherein the first protection layer further comprises a first connection pad,
wherein the second protection layer further comprises a second connection pad,
wherein the first connection pad and the second connection pad are in contact with each other,
wherein the first via extends from the first connection pad, and
wherein the second via extends from the second connection pad.

4. The semiconductor package of claim 1, wherein an uppermost memory chip further comprises a landing pad provided in an upper portion thereof, and
wherein an end portion of the second via is connected to the landing pad.

5. The semiconductor package of claim 1, wherein the first and second vias comprise a plurality of first vias and a plurality of second vias, which are arranged along a first direction parallel to a top surface of the base chip.

6. The semiconductor package of claim 5, wherein the plurality of first vias have a shape whose width along the first direction decreases as a distance to a bottom surface of the base chip decreases along a second direction perpendicular to the top surface of the base chip.

7. A semiconductor package, comprising:
a base chip; and
chip stacks on the base chip,
wherein the base chip comprises a first semiconductor substrate,
wherein each of the chip stacks comprises a plurality of memory chips and a plurality of first vias,
wherein each of the memory chips comprises a second semiconductor substrate and an interconnection layer on the second semiconductor substrate,
wherein the first semiconductor substrate has a first thickness along a first direction perpendicular to a top surface of the base chip,
wherein the second semiconductor substrate has a second thickness along the first direction,
wherein the second thickness is smaller than or equal to 10% of the first thickness, and
wherein the plurality of the first vias penetrate the plurality of memory chips.

8. The semiconductor package of claim 7, wherein the interconnection layer further comprises an insulating layer and interconnection patterns in the insulating layer, and
wherein the first via which is included in an uppermost memory chip penetrates a portion of the interconnection layer.

9. The semiconductor package of claim 7, further comprising a second via penetrating the base chip,
wherein the plurality of first vias and the second vias are electrically connected to each other.

10. The semiconductor package of claim 9, further comprising a first barrier metal on side and top surfaces of the plurality of first vias,
a second barrier metal disposed on side and bottom surfaces of the second via; and
a liner on a side surface of the second barrier metal,
wherein each of the chip stack does not have a liner.

11. The semiconductor package of claim 9, wherein the second via has a first width along a second direction parallel to the top surface of the base chip, and
the first width is smaller than or equal to about 10 μm.

12. The semiconductor package of claim 11, wherein the plurality of first vias have a first height in the first direction, and
a first aspect ratio, which is a value obtained by dividing the first height by the second width, is less than or equal to 15.

13. The semiconductor package of claim 11, wherein the second via has a first width in the second direction,
wherein the second width is larger than the first width, and
wherein the second width is smaller than or equal to about 60 μm.

14. The semiconductor package of claim 13, wherein the second via has a second height in the first direction, and
a second aspect ratio, which is a value obtained by dividing the second height by the first width, is less than or equal to 17.

15. The semiconductor package of claim 7, wherein the second thickness ranges from 0 μm to about 10 μm.

16. A semiconductor package, comprising:
a package substrate;
an interposer substrate on the package substrate;
a chip structure disposed on the interposer substrate; and
a logic chip disposed on the interposer substrate and spaced apart from the chip structure along a first direction parallel to a top surface of the package substrate,
wherein the chip structure comprises:
a base chip including a first via;
chip stacks on the base chip; and
a dummy plate on the chip stacks,
wherein the base chip comprises a first semiconductor substrate and a first protection layer on the first semiconductor substrate,
wherein the chip stacks comprise a second protection layer, a plurality of memory chips on the second protection layer, and a second via,
wherein the memory chips comprise a second semiconductor substrate and an interconnection layer on the second semiconductor substrate,
wherein the interconnection layer of an uppermost memory chips in each of the chip stacks comprises a landing pad,
wherein the second protection layer comprises a connection pad,
wherein the dummy plate comprises a third semiconductor substrate,
wherein the first semiconductor substrate has a first thickness along a second direction perpendicular to the top surface of the package substrate,
wherein the second semiconductor substrate has a second thickness along the second direction,
wherein the first thickness is larger than or equal to about 100 μm,
wherein the second thickness ranges from 0 μm to about 10 μm,
wherein the first protection layer is in contact with the second protection layer, which is included in an lowermost chip stacks, and
wherein a width of the first via along the first direction is larger than a width of the second via along the first direction.

17. The semiconductor package of claim 16, wherein the third semiconductor substrate has a third thickness along the second direction, and
the third thickness ranges from about 700 μm to about 775 μm.

18. The semiconductor package of claim 16, wherein the number of the memory chips in each of the chip stacks is 2N, where N is a positive integer.

19. The semiconductor package of claim 16, wherein the first and second vias comprise a plurality of first vias and a plurality of second vias, which are arranged along the first direction.

20. The semiconductor package of claim 16, wherein, except for the uppermost one of the chip stacks, the landing pad in one of the chip stacks is in contact with the connection pad in another chip stack.
